(19) United States
(12) Patent Application Publication
(10) Pub. No.: US 2025/0271491 A1
(43) Pub. Date: Aug. 28, 2025

(54) METHOD AND MEASUREMENT SYSTEM OF DETERMINING A QUALITY METRIC FOR A DEVICE UNDER TEST HAVING MULTIPLE TRANSMISSION ANTENNAS

(71) Applicant: Rohde & Schwarz GmbH & Co. KG, Muenchen (DE)

(72) Inventors: Matthias ROTH, Muenchen (DE); Volker FISCHER, Muenchen (DE)

(21) Appl. No.: 18/590,482

(22) Filed: Feb. 28, 2024

(51) Int. Cl. G01R 31/28

(52) U.S. Cl. CPC G01R 31/2822; G01R 31/2834

(57) ABSTRACT

The present disclosure relates to a method of determining a quality metric for a device under test having multiple transmission antennas for transmitting multiple transmission signals. Each of the multiple transmission signals is received by a reception branch having a first receiver and a second receiver, which provide a first complex-valued measurement signal and a second complex-valued measurement signal. A first quality vector for the first receiver is calculated based on the first complex-valued measurement signal and a second quality vector for the second receiver is calculated based on the second complex-valued measurement signal. A combined average of the first quality vector and of a complex conjugate of the second quality vector is determined over a predetermined number of samples, thereby obtaining a complex-valued average signal. A quality metric based on the complex-valued average signal is determined. A measurement system for determining a quality metric is also described.

### FIELD OF THE DISCLOSURE

Embodiments of the present disclosure generally relate to a method of determining a quality metric for a device under test having multiple transmission antennas. Embodiments of the present disclosure further relate to a measurement system of determining a quality metric for a device under test having multiple transmission antennas.

### BACKGROUND

Detectors are known for mapping a number of measurement points to a lower number of output results. For example, root-mean-square (RMS) detectors are used in order to determine the average power of a signal, e.g. for noise analysis. However, detectors such as RMS detectors cannot distinguish between noise that originates from the device under test (DUT) and noise added by a measurement instrument itself which comprises the detector.

Accordingly, if the measurement instrument has an intrinsic noise level that is of the same magnitude or even higher than the noise level of the device under test, the noise caused by the device under test cannot be reliably measured. In addition, a small signal of the device under test below the intrinsic noise level of the measurement instrument cannot be detected.

A known solution to this problem is to conduct a reference measurement without the device under test in the signal chain. The additional noise generated by the measurement instrument can be determined based on the reference measurement, and can be subtracted in the corresponding measurement of the device under test.

This prior art solution only works reliably to a certain extent of up to around 10 dB. In addition, performing the additional reference measurement takes additional time. Moreover, the measurement instrument may behave differently when the device under test is connected to the measurement instrument and when the device under test is not connected to the measurement instrument.

To overcome the above-mentioned issues, methods and measurement systems are known that are only applicable for a single connection between the device under test and the measurement instrument, namely for a device under test having a single output, e.g. a single transmission antenna.

Since modern communication devices typically comprise more than a single transmission antenna, there is a need for a method and a measurement system that allow for a faster analysis of the noise level of a device under test which has several transmission antennas.

### SUMMARY

Embodiments of the present disclosure provide a method of determining a quality metric for a device under test having multiple transmission antennas for transmitting multiple transmission signals. In an embodiment, the method comprises one or more of the following.

Each of the multiple transmission signals are received by a respective reception antenna connected to a corresponding reception branch having at least a first receiver and a second receiver. The first receiver and the second receiver both receive and process the same transmission signal, thereby providing a first complex-valued measurement signal and a second complex-valued measurement signal respectively.

At least one reference signal is provided that is associated with a signal to be transmitted by the device under test. A first quality vector is calculated for the first receiver based on the first complex-valued measurement signal and a second quality vector for the second receiver based on the second complex-valued measurement signal. The quality vectors are calculated with respect to the at least one reference signal.

A combined average of the first quality vector and of a complex conjugate of the second quality vector is determined over a predetermined number of samples, thereby obtaining a complex-valued average signal.

A quality metric is determined based on the complex-valued average signal.

Further, embodiments of the present disclosure relate to a measurement system for determining a quality metric for a device under test having multiple transmission antennas for transmitting multiple transmission signals. In an embodiment, the measurement system comprises multiple reception branches and at least one detector circuit. The at least one detector circuit has a first signal input, a second signal input, and an averaging sub-circuit. Each reception branch is configured to receive one of the multiple transmission signals, wherein each reception branch comprises at least two receivers such that the at least two receivers of the same reception branch receive and process the same transmission signal, thereby providing a first complex-valued measurement signal and a second complex-valued measurement signal respectively. The first signal input is connected with the first receiver and configured to receive the first complex-valued measurement signal. The second signal input is associated with the second receiver and configured to receive the second complex-valued measurement signal.

In an embodiment, the detector circuit is configured to calculate a first quality vector for the first receiver based on the first complex-valued measurement signal and a second quality vector for the second receiver based on the second complex-valued measurement signal. The quality vectors are calculated with respect to a reference signal provided which is associated with a signal to be transmitted by the device under test. The averaging sub-circuit is configured to determine a combined average of the first quality vector and of a complex conjugate of the second quality vector over a predetermined number of samples, thereby obtaining a complex-valued average signal. The averaging sub-circuit is configured to determine a quality metric based on the complex-valued average signal.

In an embodiment, the multiple transmission signals are transmitted by the multiple transmission antennas of the device under test, wherein the multiple transmission signals are obtained by applying a transmission mapping on a signal to be transmitted by the device under test. Accordingly, symbols associated with the signal to be transmitted are mapped to the multiple transmission signals in a respective order such that symbols, e.g. OFDM symbols (“Orthogonal Frequency Division Multiplexing” symbols), are transmitted on different frequency carriers (frequency domain) at certain points in time (time domain).

The main idea is to selectively remove noise originating from sources other than the device under test from the signals processed in each reception branch by averaging the cross-correlation between the first quality vector and the second quality vector over the predetermined number of samples. Accordingly, the cross-correlation between the first quality vector and the second quality vector is averaged for each reception branch. The first quality vector and the second quality vector are derived from the first complex-valued measurement signal and the second complex-valued measurement signal respectively, which are obtained by the receivers of the same reception branch, e.g. the receivers that receive and process the same transmission signal. In other words, the first complex-valued measurement signal and the second complex-valued measurement signal both are associated with the same transmission signal that is transmitted by one of the multiple transmission antennas of the device under test.

Both the amplitudes and the phases of the quality vectors are taken into account in order to determine the combined average for the respective reception branch. Hence, the quality vectors are complex-valued quality vectors. In other words, the quality vectors each comprise amplitude information and phase information, wherein both the amplitude information and the phase information are considered for determining the combined average for the respective reception branch. Accordingly, the combined average may also be called a “vector average”.

By performing the combined averaging, the resulting complex-valued average signal comprises significantly reduced noise. For example, noise introduced by a reception part of the measurement system is significantly reduced.

In an embodiment, a reception antenna is connected to the respective reception branch having at least the first receiver and the second receiver. Each receiver, first respective second, adds uncorrelated receiver noise. The cross-correlation method reduces the receiver noise, but does not affect/change the transmitter noise, namely the noise introduced by the device under test. In other words, the noise introduced by the transmission part of the measurement system, e.g. the device under test with its antenna plane/layer/domain, stays in. The measurement accuracy can be increased accordingly.

On the other hand, noise originating from other sources, e.g. from components processing the transmission signal received like the receivers in the respective reception branch, is not correlated with each other and at least partially cancels out when performing the combined average.

Thus, the noise level is effectively reduced, but without impairing the ability to analyze the noise contribution of the device under test.

In an embodiment, a fast suppression of intrinsic noise of the components processing the transmission signal received is obtained, e.g. components of the measurement system/apparatus/setup, such that the signal to noise (ratio/level) and therefore an error vector magnitude (EVM) measurement accuracy is enhanced. Further, the signal-to-noise ratio is increased for measurements of signals of the device under test, for example for measurements of small-amplitude signals of the device under test. Moreover, an additional reference measurement for determining the noise contribution of components in the signal chain other than the device under test is not necessary. Thus, the noise contribution of the device under test can reliably be analyzed based on a single measurement.

In an embodiment, the averaging sub-circuit may comprise a multiplication unit, wherein the multiplication unit is configured to multiply the first quality vector with the complex conjugate of the second quality vector, thereby obtaining a complex-valued multiplication signal.

In an embodiment, the averaging sub-circuit may further be configured to average the complex-valued multiplication signal over the predetermined number of samples, thereby obtaining the complex-valued average signal.

In an embodiment, each reception branch may comprise a filter such that the receivers of the respective reception branches are associated with specific frequency bands. This ensures that a dedicated relationship of the multiple transmission antennas and the reception antennas is provided.

Since the device under test comprises the multiple transmission antennas, the signal to be transmitted is mapped to the multiple transmission antennas based on the transmission mapping applied. The signal to be transmitted by the device under test comprises several symbols which are transmitted on different carriers and/or in a certain temporal order by the multiple transmission antennas of the device under test. Consequently, each transmission signal may relate to a certain portion of the signal to be transmitted. In other words, the several symbols to be transmitted are split into several sequences of symbols, based on which the individual transmission signals are generated. The respective sequences of symbols are transmitted by the multiple transmission antennas accordingly, for example the respective transmission signals. The splitting of the symbols of the signal to be transmitted is obtained by the transmission mapping applied on the signal to be transmitted.

Due to the multiple transmission antennas, the multiple transmission signals are transmitted which are received by the corresponding reception branches, for example respective reception antennas connected with the reception branches. Since each reception branch comprises the at least two receivers, the impact of the reception branch on the signal received with regard to noise can be reduced by determining the combined average as outlined above.

In an embodiment, a combined average of the first quality vector and of a complex conjugate of the second quality vector is determined over a predetermined number of samples, thereby obtaining a complex-valued average signal corresponds to cross-correlating the first quality vector and the second quality vector, thereby obtaining a cross-correlated signal. Accordingly, the quality metric may also be determined based on the cross-correlated signal.

Consequently, the measurement system is also configured to cross-correlate the first quality vector and the second quality vector, thereby obtaining a cross-correlated signal and to determine the quality metric based on the cross-correlated signal.

An aspect provides that the measurement system comprises, for example, a measurement instrument that comprises the multiple reception branches and the at least one detector circuit. Each of the reception branches is connected to a respective reception antenna. Each of the reception branches has at least two parallel measurement channels having the respective receiver. The measurement system further comprises a separately formed device under test with the multiple transmission antennas via which the multiple transmission signals are transmitted over-the-air, which are received by the multiple reception antennas of the measurement instrument. Accordingly, the measurement system may comprise two separately formed devices, namely the measurement instrument and the device under test. The device under test corresponds to the transmission part, whereas the measurement instrument corresponds to the reception part of the measurement system.

Instead of transmitting the multiple transmission signals over-the-air, the multiple transmission signals in an embodiment may also be transmitted via a cable connection and respective ports (instead of antennas).

In an embodiment, a splitter may be provided in each reception branch, e.g. between the reception antenna and the receivers. In other words, the splitter ensures that at least two measurement channels are provided in each reception branch, wherein each measurement channel has one receiver that processes the transmission signal received, thereby providing the respective complex-valued measurement signal.

An aspect provides that each complex-valued measurement signal comprises, for example, a symbol sequence associated with the respective transmission signal, namely a received symbol sequence, wherein the symbol sequences received are processed in order to calculate the quality vectors. As indicated above, the signal to be transmitted by the device under test comprises several symbols, wherein the symbols are mapped to the multiple transmission antennas such that each transmission signal is based on a subset of the overall symbols of the signal to be transmitted, namely a respective symbol sequence. The symbol sequences together form the symbols of the signal to be transmitted by the device under test. The complex-valued measurement signals obtained by the receivers, for example the symbol sequences received, are processed further in order to calculate the quality vectors, wherein the at least one reference signal is also taken into account. In other words, the quality vectors may be determined by putting the complex-valued measurement signals and the at least one reference signal in relation with each other, for example the symbol sequences associated with the complex-valued measurement signals and the symbols associated with the at least one reference signal.

In an embodiment, the at least one reference signal may be indicative for the respective transmission antenna or the transmission signal, for example the symbols to be transmitted by the respective transmission antenna by the corresponding transmission signal.

Another aspect provides that the at least one reference signal, for example, is inputted to a detector circuit that calculates the respective quality vectors based on the reference signal inputted and the complex-valued measurement signals. The at least one detector circuit may have an input configured to receive the at least one reference signal. The at least one detector circuit is configured to calculate the respective quality vectors based on the reference signal(s) inputted and the complex-valued measurement signals. The reference signal that is associated with the signal to be transmitted by the device under test may be directly inputted such that the detector circuit is enabled to compare the complex-valued measurement signals received with the reference signal(s). Generally, the at least one reference signal may relate to the part of the signal to be transmitted, which is to be transmitted by the respective transmission antenna, namely the signal portion of the signal to be transmitted. In other words, the signal to be transmitted, e.g. the overall symbols to be transmitted, are split, processed and transmitted via the multiple transmission antennas according to the transmission mapping applied, such that signal portions for each transmission antenna are obtained, wherein the signal portions together form the signal to be transmitted, for example when considering the respective symbols associated with the signal portion(s) and the signal to be transmitted.

Hence, multiple reference signals may be provided which are indicative for each reception branch, namely each of the multiple transmission signals or the symbols to be transmitted by each of the multiple transmission antennas.

According to a further aspect, the at least one reference signal, for example, is determined by a detector circuit from processing the complex-valued measurement signals, for example a summed signal obtained from all complex-valued measurement signals, wherein the respective quality vectors are calculated based on the reference signal determined and the complex-valued measurement signals. Hence, the at least one detector circuit may be configured to determine the at least one reference signal, for example the multiple reference signals, from processing the complex-valued measurement signals, wherein at least one detector circuit is configured to calculate the respective quality vectors based on the reference signal determined and the complex-valued measurement signals. Consequently, it is not necessary to directly input the at least one reference signal since the detector circuit is enabled to determine/calculate the at least one reference signal by processing the associated complex-valued measurement signals.

For instance, the complex-valued measurement signals are processed in a constellation layer in order to determine constellation points for the complex-valued measurement signals. In the constellation layer, the actual constellation points may be identified and associated with a modulation scheme used by the device under test, thereby determining the ideal constellation points. Based thereon, the at least one reference signal can be determined. In other words, the at least one reference signal is found at the constellation layer. Moreover, deviations of the actual constellation points from the ideal constellation points may be identified (simultaneously).

As indicated above, the device under test applies the transmission mapping on the signal to be transmitted such that the overall symbols of the signal to be transmitted are mapped to the multiple transmission antennas.

In an embodiment, the measurement instrument may be configured for transmission demapping to obtain symbol streams from the complex-valued measurement signals. In an embodiment, the complex-valued measurement signals are used for MIMO decoding respective transmission demapping such that the measured symbol streams are obtained, namely the sequences of symbols, but on reception site.

In an embodiment, the measurement instrument is configured to process the symbol streams obtained in a constellation diagram layer. When processing the symbol streams in the constellation diagram layer, decisions with regard to the respective symbols are made such that original symbol streams are determined, which are deemed to be used by the device under test, namely the transmitter. In other words, the probable symbols transmitted are obtained. The original symbol streams are deemed to correspond the sequences of symbols, based on which the individual transmission signals were generated. In other words, the real symbols, for example the real symbol sequences, are determined in the constellation diagram layer due to symbol decisions made.

Afterwards, the measurement instrument may apply a MIMO encoding respective transmission mapping, e.g. applying the transmission mapping, on the original symbol streams. By doing so, reference symbols are generated that correspond to the complex symbols obtained after the MIMO encoding on transmission side, namely for each transmission antenna. In other words, the multiple transmission signals are determined accordingly.

An example of this can be illustrated as follows. Each receiver in each reception branch receives a respective complex-valued measurement signal \tilde{t} such that the entire measurement instrument gathers the several complex-valued measurement signals:

$$\tilde{t} : = {\tilde{t}}^{( u )} : = ( \begin{matrix}{\tilde{t}}^{( u , 1 )} \\ ⋮ \\ {\tilde{t}}^{( u , m )}\end{matrix} ) ,$$

wherein u∈{1, 2} in case of two receivers per reception branch. Generally, u∈{1 . . . r} for the respective number of receivers per reception branch. Moreover, m designates the number of transmission antennas of the device under test.

Hence, \tilde{t}^{(u,p)} is the complex-valued measurement signal received by the respective receiver u in the reception branch associated with the transmission antenna p. Consequently, \tilde{t}^{(u)} relates to the complex-valued measurement signals, namely the respective complex-valued measurement symbols associated with the complex-valued measurement signals, based on which the MIMO decoding respective transmission demapping is done.

The MIMO decoding respective transmission demapping can be expressed as follows:

$$\tilde{s} = {M}^{- 1} * \tilde{t} ,$$

wherein \tilde{s} relates to measured symbol streams obtained after MIMO decoding respective transmission demapping, e.g. applying the transmission demapping M⁻¹ on the complex-valued measurement signals received, e.g. the respective complex-valued measurement symbols.

The measured symbols streams \tilde{s} are further processed for symbol decision in the constellation diagram layer in order to determine the corresponding symbols s_{dec} (on reception site). This can be expressed as follows:

$${s}_{d e c} := decide ( \tilde{s} ) .$$

These symbols s_{dec} obtained are deemed to relate to the symbols s used by the device under test prior to MIMO mapping (on transmission site), namely the “real transmitted symbols”. This can be expressed as follows:

s≅s_{dec}.

Finally, these symbols s_{dec} are used to generate the reference symbols t_{ref} for the at least one reference signal, namely by a MIMO encoding respective transmission mapping, e.g. applying the transmission mapping M on the symbols. This can be expressed as follows:

$${t}_{ref} = M * {s}_{dec} .$$

As indicated above, the reference symbols t_{ref} obtained relate to the at least one reference signal t that is used for calculating the quality vectors. Consequently, the at least one reference signal t may be derived from the several complex-valued measurement signals.

The quality metric may be determined for each of the multiple transmission antennas individually. Hence, the at least one detector circuit may be configured to determine the quality metric for each of the multiple transmission antennas individually. As indicated above, the reference signal may relate to the signal portion to be transmitted by each individual transmission antenna, namely the transmission signal. Based thereon the combined average is determined for each individual antenna such that the quality metric is also determined for each individual antenna.

Alternatively or additionally, the quality metric is determined for all of the multiple transmission antennas commonly. Hence, the at least one detector circuit may be configured to determine the quality metric for all of the multiple transmission antennas commonly. In an embodiment, the combined average is determined for the sum of all antennas such that the quality metric is also determined for all antennas commonly.

For instance, the quality vectors are averaged in time and/or frequency. Hence, the at least one detector circuit may be configured to average the quality vectors in time and/or frequency. Accordingly, the symbol index (time domain) as well as the carrier index (frequency domain) may be taken into consideration when determining the combined average and the quality metric.

According to a specific embodiment, the quality vectors are error vectors and the quality metric is an error vector magnitude (EVM). Generally, the quality vectors, e.g. the error vectors, may be expressed by:

$${ε}^{( u , p )} : = {t}^{( p )} - {\tilde{t}}^{( u , p )} ,$$

wherein ε^{(u,p)} is the respective quality vector, u∈{1 . . . r} is the receiver in the respective reception branch, e.g. 1 or 2 in case of two receivers, p∈{1 . . . m} is the transmission antenna of the device under test, t^{(p)} is the reference signal for the respective transmission antenna p, and \tilde{t}^{(u,p)} is the complex-valued measurement signal received by the respective receiver u in the reception branch associated with the transmission antenna p.

The quality metric, e.g. the error vector magnitude (EVM), for the individual transmission antennas can be expressed by:

$${E}^{( p )} : = \frac{1}{N * {N}_{F F T}} \vert {\sum }_{{0 \leq i < N}_{0 \leq k < {N}_{F F T}}} {ε}_{i , k}^{( 1 , p )} * {ε}_{i , k}^{( 2 , p )} \vert$$

wherein i∈{0, 1, . . . N−1} is the symbol index (time domain), and k∈{0, 1, . . . N_{FFT}−1} is the carrier index. Moreoverε_{i,k}^{*(2,p)}, is the complex conjugate of ε_{i,k}^{(2,p)}, namely conjugate (ε_{i,k}^{(2,p)}). In other words, the first quality vector is expressed by ε_{i,k}^{(1,p)}, whereas the complex conjugate of the second quality vector is expressed by ε_{i,k}^{*(2,p)}. In the example given above, the combined average is determined over the samples in time domain due to the symbol index as well as samples in frequency domain due to the carrier index.

In an embodiment, the combined average for the individual transmission antennas relates to:

$$\frac{1}{N * {N}_{F F T}} * {\sum }_{{0 \leq i < N}_{0 \leq k < {N}_{F F T}}} {ε}_{i , k}^{( 1 , p )} * {ε}_{i , k}^{( 2 , p )}$$

The quality metric, e.g. the error vector magnitude (EVM), for all transmission antennas commonly can be expressed by:

$$E := \frac{1}{m * N * {N}_{FFT}} \vert {\sum }_{\begin{matrix}0 \leq i < N \\ 0 \leq k < {N}_{FFT} \\ 1 \leq p \leq m\end{matrix}} {ε}_{i , k}^{( 1 , p )} * {ε}_{i , k}^{* ( 2 , p )} \vert$$

Accordingly, the combined average is:

$$\frac{1}{m * N * {N}_{FFT}} * {\sum }_{\begin{matrix}0 \leq i < N \\ 0 \leq k < {N}_{FFT} \\ 1 \leq p \leq m\end{matrix}} {ε}_{i , k}^{( 1 , p )} * {ε}_{i , k}^{* ( 2 , p )}$$

### DESCRIPTION OF THE DRAWINGS

The foregoing aspects and many of the attendant advantages of the claimed subject matter will become more readily appreciated as the same become better understood by reference to the following detailed description, when taken in conjunction with the accompanying drawings, wherein:

FIG. 1 schematically shows a variant of the measurement system according to an embodiment of the present disclosure;

FIG. 2 shows schematically shows another variant of the measurement system according to an embodiment of the present disclosure, and

FIG. 3 schematically shows a simplified overview of the measurement system according to an embodiment of the present disclosure.

### DETAILED DESCRIPTION

The detailed description set forth below in connection with the appended drawings, where like numerals reference like elements, is intended as a description of various embodiments of the disclosed subject matter and is not intended to represent the only embodiments. Each embodiment described in this disclosure is provided merely as an example or illustration and should not be construed as preferred or advantageous over other embodiments. The illustrative examples provided herein are not intended to be exhaustive or to limit the claimed subject matter to the precise forms disclosed.

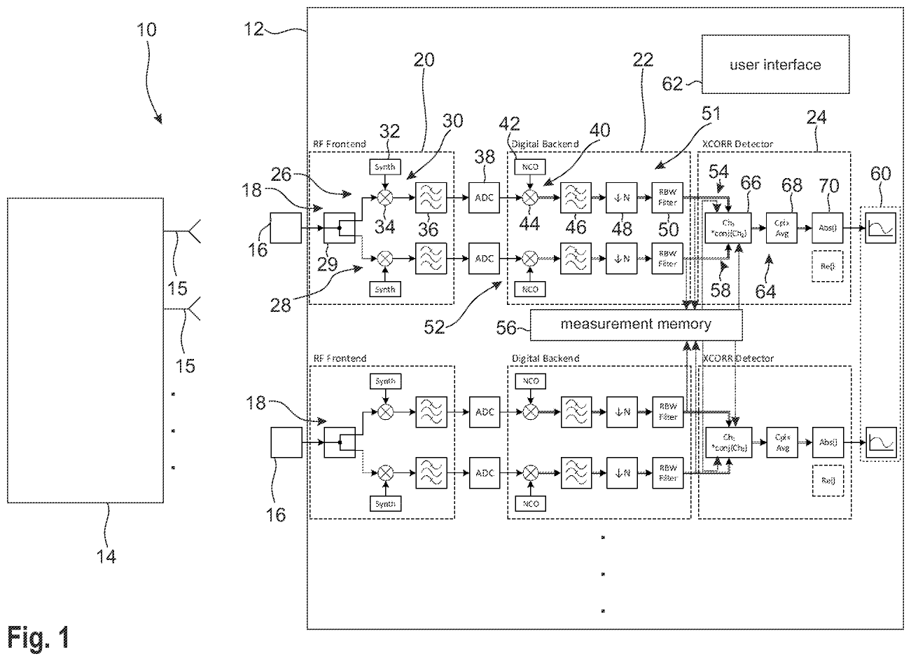

FIG. 1 schematically shows a measurement system 10 comprising a measurement instrument 12 and a device under test 14 having multiple transmission antennas 15. In the shown embodiment, only two transmission antennas 15 are shown for the sake of clarity and simplicity. In general, the measurement instrument 12 is configured to analyze transmission signals received from the device under test 14 in order to analyze certain properties of the device under test 14.

For example, the measurement instrument 12 may be a signal analyzer, a spectrum analyzer, an electromagnetic interference (EMI) test receiver, an EMI measuring receiver, an oscilloscope, a digital oscilloscope, or a power sensor. However, the measurement instrument 12 may be established as any other type of measurement instrument, depending on which aspects of the performance of the device under test 14 are to be tested.

The device under test 14 may be established as any electronic device that is configured to generate radio-frequency (RF) signals. For example, the device under test 14 comprises one or several electronic circuits generating RF signals, wherein the performance of the electronic circuit(s) is assessed by the measurement instrument 12.

The device under test 14 is connected with the measurement instrument 12 in a signal-transmitting manner. Therein and in the following, the term “connected in a signal transmitting manner” is understood to denote a wireless connection that is configured to transmit signals between the respective devices or components. For example, the device under test 14 may transmit wireless electromagnetic signals, which are received via multiple reception antennas 16 of the measurement instrument 12.

In the embodiment shown, the measurement instrument 12 comprises multiple reception branches 18 that are connected to a respective reception antenna 16. In FIG. 1, only two reception branches 18 are shown for the sake of clarity and simplicity. Generally, more than two reception branches 18 may be provided. Hereinafter, reference is made to one of the multiple reception branches 18. Irrespective of the specific number of reception branches 18, each of the multiple reception branches 18 has an RF frontend 20 and a digital backend 22.

The measurement instrument 12 has at least one detector circuit 24 that is connected with the respective digital backend 22 of the multiple reception branches 18. In an embodiment, multiple detector circuits 24 may be provided, e.g. one per reception branch 18, or one common detector circuit 24 for all reception branches 18.

Generally, the components of the reception branches 18, for example the RF frontend 20 and the digital backend 22, as well as the detector circuit 24 may be established on at least one signal processing circuit of the measurement instrument 12.

Each reception branch 18 comprises a first measurement channel 26 and a second measurement channel 28 that are each connected to the respective reception antenna 16, e.g. via a splitter 29. The measurement channels 26, 28 are arranged in parallel, such that a transmission signal received from the device under test 14 via the respective reception antenna 16 is forwarded to and processed by both measurement channels 26, 28 in parallel.

The measurement channels 26, 28 are functionally identical, i.e. the electronic components of the first measurement channel 26 are identical in construction to the electronic components of the second measurement channel 28. Thus, only the first measurement channel 26 is described in the following, as the explanations given hereinafter likewise apply to the second measurement channel 28.

The first measurement channel 26 comprises a first mixer sub-circuit 30 that is associated with the RF frontend 20 of the respective reception branch 18. In general, the first mixer sub-circuit 30 is configured to down-convert the transmission signal received from the device under test 14 to an intermediate frequency being suitable for processing by the electronic components downstream of the first mixer sub-circuit 30. As usual, the first mixer sub-circuit 30 comprises a local oscillator input 32 that is configured to receive a local oscillator signal.

The first mixer sub-circuit 30 further comprises a mixer unit 34 having circuitry that is configured to mix the transmission signal received from the respective transmission antenna 15 of the device under test 14 with the local oscillator signal, and a band-pass filter 36 that is configured to appropriately filter the resulting mixed signal in order to down-convert the transmission signal to the intermediate frequency.

In an embodiment, the frequency of the local oscillator signal may be constant. Alternatively, the frequency of the local oscillator signal may be time-variant, i.e. a frequency sweep may be applied to the local oscillator signal.

The first measurement channel 26 further comprises an analog-to-digital converter (ADC) 38 that is configured to digitize the signal output by the first mixer sub-circuit 30. The analog-to-digital converter (ADC) 38 is located between the RF frontend 20 and the digital backend 22.

In the embodiment shown, the first measurement channel 26 further comprises a second mixer sub-circuit 40 having an oscillator input 42, a mixer unit 44, and a filter unit 46. In general, the second mixer sub-circuit 40 is configured to mix the digitized signal received from the ADC 38 into the complex baseband by any suitable technique known in the art. In an embodiment, the second mixer sub-circuit 40 may be configured to generate an IQ signal based on the digitized signal received from the ADC 38 by any suitable technique known in the art.

The frequency of the local oscillator signal received via the oscillator input 42 may be constant. Alternatively, the frequency of the local oscillator signal received via the oscillator input 42 may be time-variant, i.e. a frequency sweep may be applied to the local oscillator signal.

In the example embodiment shown in FIG. 1, the first measurement channel 26 further comprises a down-converter unit 48 and a resolution bandwidth (RBW) filter 50. The down-converter unit 48 is configured to down-sample the signal received from the second mixer sub-circuit 40 by a predetermined factor, i.e. to reduce the number of samples by a predetermined factor. The RBW filter 50 determines the resolution bandwidth of the first measurement channel 26. The resolution bandwidth may be fixed or may be adjustable. In an embodiment, the resolution bandwidth may be adjustable by a user.

Summarizing, an input signal received from the device under test 14 is processed by the electronic components of the first measurement channel 26 described above, thereby generating a first complex-valued measurement signal.

Accordingly, the electronic components mentioned before in the digital backend 22 constitute a first receiver 51 that receives and processes the transmission signal, thereby providing the first complex-valued measurement signal.

Likewise, the same transmission signal received from the respective transmission antenna 15 of the device under test 14 is processed by the electronic components of the second measurement channel 28 as well, thereby generating a second complex-valued measurement signal. Again, the electronic components of the second measurement channel 28 constitute a second receiver 52 that receives and processes the transmission signal, thereby providing the second complex-valued measurement signal.

Accordingly, the first receiver 51 and the second receiver 52 both receive and process the same transmission signal, thereby providing the first complex-valued measurement signal and the second complex-valued measurement signal respectively.

In an embodiment, the two parallel measurement channels 26, 28 are synchronized. In other words, the same transmission signal is processed by the two parallel measurement channels 26, 28 simultaneously.

The first complex-valued measurement signal is (directly) forwarded to a first signal input 54 of the detector circuit 24. Alternatively or additionally, the first complex-valued measurement signal is (at least temporarily) saved in a measurement memory 56 of the measurement instrument 12.

The second complex-valued measurement signal is (directly) forwarded to a second signal input 58 of the detector circuit 24. Alternatively or additionally, the second complex-valued measurement signal is (at least temporarily) saved in the measurement memory 56.

In general, the detector circuit 24 is configured to apply mathematical operations to the complex-valued measurement signals. For instance, the complex-valued measurement signals are transformed into an output signal, i.e. into a measurement trace to be displayed on a display 60 of the measurement instrument 12.

In an embodiment, the transmission signal may be received from the respective transmission antenna 15 of the device under test 14 and processed by the corresponding reception branch 18, e.g. the measurement channels 26, 28, and the detector circuit 24 connected thereto in real time. Alternatively, the transmission signal may be received from the respective transmission antenna 15 of the device under test 14, processed by the corresponding reception branch 18, e.g. the measurement channels 26, 28, wherein the complex-valued measurement signals may be saved in the measurement memory 56.

The saved complex-valued measurement signals may later be forwarded to the signal inputs 54, 58 for further processing by the detector circuit 24.

The type of the mathematical operations applied to the measurement signals depends on a detector mode of the detector circuit 24. The detector circuit 24 may be switchable between different detector modes, wherein the detector modes comprise a cross correlation detector mode and one or several of the following detector modes: a sample detector mode, a minimum detector mode, a maximum detector mode, an auto peak detector mode, an average detector mode, and a root mean square detector mode.

In an embodiment, for the sample detector mode, the minimum detector mode, the maximum detector mode, the auto peak detector mode, the average detector mode, and the root mean square detector mode, at least one of the complex-valued measurement signals may be converted into a real-valued measurement signal before processing by the detector circuit 24.

For example, at least one conversion unit may be arranged upstream of the first signal input 54 and/or upstream of the second signal input 58, wherein the at least one conversion unit includes circuitry configured to convert the first complex-valued measurement signal and/or the second complex-valued measurement signal into a real-valued measurement signal.

Alternatively, the detector circuit 24 may comprise the conversion unit.

In an embodiment, in the sample detector mode, the minimum detector mode, the maximum detector mode, the auto peak detector mode, the average detector mode, and the root mean square detector mode, only one of the complex-valued measurement signals may be converted into a real-valued measurement signal and processed by the detector circuit 24.

For example, a user may select one or several detector modes to be applied to the complex-valued measurement signals via a user interface 62.

In the following, the basic concept of the cross correlation detector mode is explained in more detail with reference to FIG. 1.

In the cross correlation detector mode, the detector circuit 24 comprises an averaging sub-circuit 64 having a multiplication unit 66, an averaging unit 68, and an output unit 70.

The multiplication unit 66 is configured to multiply a first signal y₁(k) with a complex conjugate of a second signal y₂(k), thereby obtaining a complex-valued multiplication signal y(k), i.e.

$$y ( k ) = {y}_{1} ( k ) \cdot {y}_{2}^{*} ( k ) .$$

The averaging unit 68 is configured to average the complex-valued multiplication signal over a predetermined number of samples N, thereby obtaining a complex-valued average signal.

Accordingly, if y₁(k) and y₂*(k) are in the frequency domain, the complex-valued average signal may correspond to the trace of the cross-correlation matrix of the first complex-valued measurement signal and the second complex-valued measurement signal, divided by the predetermined number of samples N.

The output unit 70 determines the absolute value (Abs) of the complex-valued average signal or the real part of the complex-valued average signal, thereby obtaining an output signal of the detector circuit 24.

This way, noise originating in the measurement channels 26, 28 cancels at least partially, while the wanted signal (including a noise contribution) of the device under test 14 are preserved.

This can be seen as follows. The complex-valued measurement signals outputted by the digital backend 22 of the respective reception branch 18 can be split into a correlated part from the device under test 14 (a) and two uncorrelated noise parts (n₁ and n₂) from the measurement channels 26, 28:

$${y}_{1} = a + {n}_{1}$$

$${y}_{2} = a + {n}_{2}$$

The output signal (Det) of the detector circuit 24 then is

$$Det = \vert \frac{1}{N} \cdot {\sum }_{i = 0}^{N - 1} {y}_{1 i} \cdot {y}_{2 i}^{*} \vert = \vert \frac{1}{N} \cdot {\sum }_{i = 0}^{N - 1} {\vert {a}_{i} \vert}^{2} + {a}_{i} \cdot {n}_{2 i}^{*} + {a}_{i}^{*} \cdot {n}_{1 i} + {n}_{1 i} \cdot {n}_{2 i}^{*} \vert$$

The first term, i.e. 1/N Σ|aᵢ|², corresponds to the average power of the transmission signal received from the respective transmission antenna 15 of the device under test 14 over time, which corresponds to the desired detector result. The further terms correspond to multiplications of uncorrelated signals, and thus cancel at least partially. For example, the further terms correspond to noise originating in the measurement channels 26, 28. In an embodiment, it has turned out that these unwanted noise contributions are reduced approximately by 5·log₁₀(N) dB or by 1/\sqrt{N}, respectively.

The result for the output signal Det given above corresponds to the absolute value of the complex-valued average signal. Alternatively, the output signal Det may be given by:

$$Det = Re \{ \frac{1}{N} \cdot {\sum }_{i = 0}^{N - 1} {y}_{1 i} \cdot {y}_{2 i}^{*} \} = Re \{ \frac{1}{N} \cdot {\sum }_{i = 0}^{N - 1} {\vert {a}_{i} \vert}^{2} + {a}_{i} \cdot {n}_{2 i}^{*} + {a}_{i}^{*} \cdot {n}_{1 i} + {n}_{1 i} \cdot {n}_{2 i}^{*} \}$$

As can be seen from a comparison of the two possible results for the output signal Det, the two results are the same for N→∞.

In an embodiment, the predetermined number of samples N may be adjustable, e.g. via the user interface 62. In general, increasing the predetermined number of samples N leads to an enhanced noise suppression, as the non-correlated portions of the noise, i.e. the unwanted noise portions, are suppressed more the larger the number of the predetermined samples N is. Increasing the predetermined number of samples N also leads to a smoothening of the output signal, i.e. of the measurement trace, as N samples of the complex-valued measurement signals are mapped onto a single output signal sample.

As the predetermined number of samples N is adjustable, the detector circuit 24 can be adapted for different requirements, ranging from high resolution to high noise suppression.

The output signal(s) provided by the averaging sub-circuit 64 is (are) displayed on the display 60 of the measurement instrument 12.

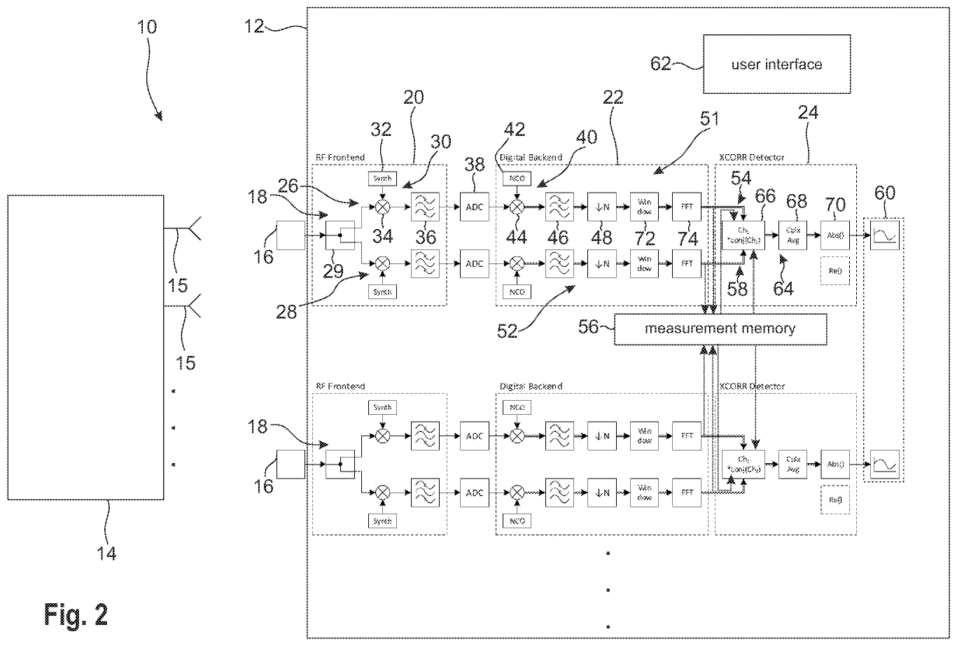

FIG. 2 shows a second embodiment of the measurement system 10, wherein only the differences compared to the first variant described above are explained in the following.

Compared to the first embodiment described above regarding FIG. 1, the RBW filter 50 is replaced with a window unit 72 and a Fourier transform unit 74. The window unit 72 is configured to apply a window function to the signal output by the down-converter unit 48, thereby determining the resolution bandwidth of the measurement channels 26, 28. The Fourier transform unit 74 is configured to determine a fast Fourier transform (FFT) of the signal output by the window unit 72.

Accordingly, in the second embodiment of the measurement system 10, the complex-valued measurement signals are established as a Fourier transformed signal, respectively.

In other words, the Fourier transform unit 74 determine a series of Fourier transforms of the respective signal processed over a predetermined time interval. Therein, the time intervals associated with consecutive Fourier transforms may overlap.

It is noted that, alternatively or additionally to the embodiment shown in FIG. 2, the measurement memory 56 may be connected to the down-converter units 48 downstream of the down-converter units 48. Further, the measurement memory 56 may be connected to the window units 72 upstream of the window units 72.

Accordingly, the signals output by the down-converter units 48 may be saved in the measurement memory 56, and may be processed by the window units 72, Fourier transform units 72 and detector circuit 24 later. In other words, the Fourier transforms may be determined and subsequently be processed by the detector circuit 24 offline. However, it is to be understood that the Fourier transforms may be determined and subsequently be processed by the detector circuit 24 in real-time, such that a real-time analysis of the input signal received from the device under test 14 is provided.

The multiplication unit 66 multiplies the first signal FFT₁(k) with a complex conjugate of the second signal FFT₂*(k), thereby obtaining a complex-valued multiplication signal FFT(k), i.e.

$$FFT ( k ) = {FFT}_{1} ( k ) \cdot {FFT}_{2}^{*} ( k ) .$$

The Fourier transformed signals (FFT1, FFT2, etc.) are generally complex-valued measurement signals such that they comprise both time and frequency information.

Accordingly, the averaging sub-circuit 64 may average a predetermined number of samples N of the Fourier transformed signals in time domain, namely the symbol index.

Alternatively or additionally, the averaging sub-circuit 64 may average the Fourier transformed signals over a predetermined number of samples in frequency domain, namely the carrier index. In other words, the averaging sub-circuit 64 may perform the combined average over subsequent samples of the Fourier transformed signals, and/or over adjacent bins of the Fourier transformed signals.

In an embodiment, the step of determining a combined average of the first quality vector and of a complex conjugate of the second quality vector over a predetermined number of samples, thereby obtaining a complex-valued average signal corresponds to cross-correlating the first quality vector and the second quality vector, thereby obtaining a cross-correlated signal. Accordingly, the quality metric may also be determined based on the cross-correlated signal.

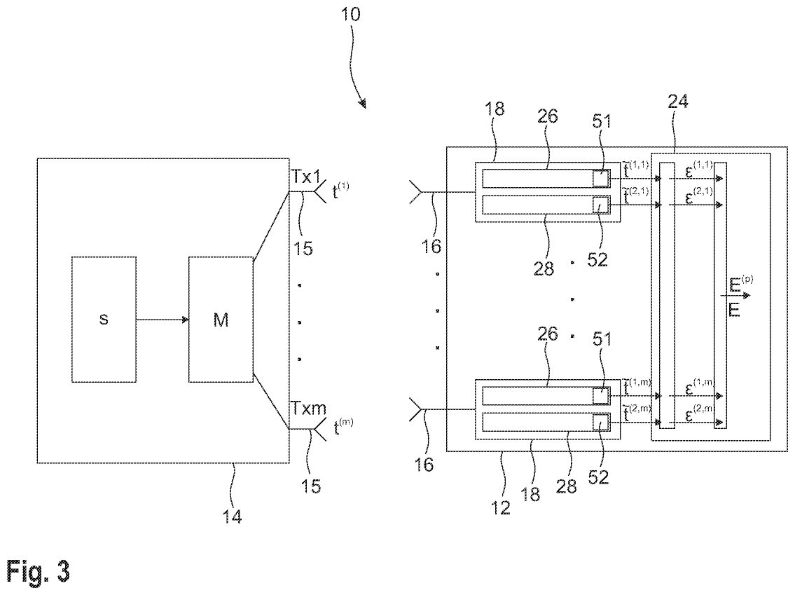

Besides the general concept of the cross correlation detector mode described above, the device under test 14 generally comprises the multiple transmission antennas 15 that are used for transmitting multiple transmission signals to be received by the multiple reception antennas 16 of the measurement instrument 12. An example of this arrangement is shown in FIG. 3 in a schematic manner.

Accordingly, the device under test 14 is associated with a data source 76 in which complex symbols s are provided that are associated with a signal to be transmitted by the device under test 14. The data source 76 may be a storage medium of the device under test 14 for (at least temporarily) storing the complex symbols s or an interface for receiving the complex symbols s to be transmitted.

In an embodiment, the device under test 14 further comprises a signal processing circuit 78 that accesses the complex symbols s to be transmitted while applying a transmission mapping M, e.g. a MIMO mapping matrix, in order to map the complex symbols s to be transmitted to the multiple transmission signals to be transmitted via the multiple transmission antennas 15.

In FIG. 3, m transmission antennas 15 are shown and labelled by Tx1 . . . Txm. The transmission signals transmitted by the transmission antennas 15 each comprise complex symbols t which are obtained after the MIMO encoding, namely after applying the transmission mapping M or the MIMO mapping matrix.

Therefore, the individual transmission signals can be expressed by

t:=Ms
wherein s relates to the complex symbols to be transmitted, M relates to the MIMO mapping matrix to be applied, e.g. the transmission mapping, and t relates to the complex symbols obtained for the individual transmission signals to be transmitted by the respective transmission antennas 15 of the device under test 14.

As also shown in FIG. 3, the measurement instrument 12 comprises multiple reception antennas 16 connected with multiple reception branches 18. In an embodiment, the multiple reception antennas 16 or the multiple reception branches 18 are associated with the multiple transmission antennas 15 appropriately. In an embodiment, the number of reception antennas 16 equals the number of reception branches 18, which in turn equals the number of transmission antennas 15.

Each reception branch 18 comprises the at least two measurement channels 26, 28 as described above with respect to FIG. 1 in detail, wherein the receivers 51, 52 of the measurement channels 26, 28 receive and process the same transmission signal, thereby providing the first complex-valued measurement signal and the second complex-valued measurement signal respectively.

As shown in FIG. 3, the first complex-valued measurement signal and the second complex-valued measurement signal comprise the received complex symbols \tilde{t}, wherein indices are provided for indicating the reception branch 18 and the respective receiver 51, 52 in the reception branch 18, for instance \tilde{t}^{(1,1)} for the received complex symbols in the first reception branch 18 by the first receiver 51 or \tilde{t}^{(2,m)} for the received complex symbols in the m-th reception branch 18 by the second receiver 52.

Since the transmitted complex symbols t are different for the individual transmission antennas 15 due to the transmission mapping M, the received complex symbols \tilde{t} are also different.

Consequently, a reference signal may be provided for each transmission antenna 15 that comprises the complex symbols t to be transmitted. The reference signal may be inputted or derived from the several complex-valued measurement signals as will be described later in more detail.

When taking the reference signal and the corresponding complex-valued measurement signal into account, for example the complex symbols t to be transmitted as well as the received complex symbols \tilde{t}, a quality vector can be determined, for example for each reception branch 18 as well as each receiver 51, 52 in the corresponding reception branch 18 separately: ε

$${ε}^{( u , p )} := {t}^{( p )} - {\tilde{t}}^{( u , p )} ,$$

wherein ε^{(u,p)} is the respective quality vector, u∈{1 . . . r} is the receiver 51, 52 in the respective reception branch, e.g. 1 or 2 in case of two receivers, p∈{1 . . . m} is the transmission antenna 15 of the device under test 14. Hence, t^{(p)} is the complex symbols to be transmitted for the respective transmission antenna p, which is obtained from the reference signal for the respective antenna. Further, \tilde{t}^{(u,p)} is the received complex symbols, namely the symbols of the complex-valued measurement signal, received by the respective receiver u in the reception branch 18 associated with the transmission antenna p.

These quality vectors ε^{(u,p)} may relate to error vectors since they are indicative of the deviations of the received complex symbols from the ideal complex symbols, namely the intended ones, thereby providing information with regard to noise and/or distortions introduced by the device under test 14 and the measurement instrument 12.

As indicated above, the contribution of the measurement instrument 12 can be averaged out by performing the cross-correlation.

Consequently, a quality metric like an error vector magnitude (EVM) can be determined for the individual transmission antennas 15 as follows:

$${E}^{( p )} := \frac{1}{N * {N}_{FFT}} \vert {\sum }_{\begin{matrix}0 \leq i < N \\ 0 \leq k < {N}_{FFT}\end{matrix}} {ε}_{i , k}^{( 1 , p )} * {ε}_{i , k}^{* ( 2 , p )} \vert$$

wherein i∈{0, 1, . . . N−1} is the symbol index (time domain), and k∈{0, 1, . . . N_{FFT}−1} is the carrier index. Moreoverε_{i,k}^{*(2,p)}, is the complex conjugate of ε_{i,k}^{(2,p)}, namely conjugate (ε_{i,k}^{(2,p)}). In other words, the first quality vector derived from the first complex-valued measurement signal is expressed by ε_{i,k}^{(1,p)}, whereas the complex conjugate of the second quality vector is expressed by ε_{i,k}^{*(2,p)}. The second quality vector is derived from the second complex-valued measurement signal. In the example given above, the combined average is determined over the samples in time domain due to the symbol index as well as samples in frequency domain due to the carrier index.

In an embodiment, the combined average for the individual transmission antennas 15 relates to:

$$\frac{1}{N * {N}_{FFT}} * {\sum }_{\begin{matrix}0 \leq i < N \\ 0 \leq k < {N}_{FFT}\end{matrix}} {ε}_{i , k}^{( 1 , p )} * {ε}_{i , k}^{* ( 2 , p )}$$

The quality metric, e.g. the error vector magnitude (EVM), for all transmission antennas 15 can be determined commonly by:

$$E := \frac{1}{m * N * {N}_{FFT}} \vert {\sum }_{\begin{matrix}0 \leq i < N \\ 0 \leq k < {N}_{FFT} \\ 1 \leq p \leq m\end{matrix}} {ε}_{i , k}^{( 1 , p )} * {ε}_{i , k}^{* ( 2 , p )} \vert$$

In an embodiment, the average is formed over all transmission antennas 15 while taking all reception branches 18 into account. Accordingly, the combined average is:

$$\frac{1}{m * N * {N}_{FFT}} * {\sum }_{\begin{matrix}0 \leq i < N \\ 0 \leq k < {N}_{FFT} \\ 1 \leq p \leq m\end{matrix}} {ε}_{i , k}^{( 1 , p )} * {ε}_{i , k}^{* ( 2 , p )}$$

Instead of determining the absolute value of the combined average in order to obtain the quality metric, the respective real part of the complex-valued combined average may be determined as described above with respect to FIG. 1.

As mentioned before, the quality vectors are determined while processing the respective complex-valued measurement signal and the corresponding reference signal.

The reference signals for the transmission antennas 15 or the transmission signals may be inputted to the measurement instrument 12, for example the detector circuit 24, for instance via the user interface 62. Consequently, the detector circuit 24 calculates the respective quality vectors based on the reference signal inputted and the complex-valued measurement signals.

Alternatively, the respective reference signals for the transmission antennas 15 or the transmission signals may be determined by the detector circuit 24 from processing the complex-valued measurement signals as will be described in more detail hereinafter. Consequently, the respective quality vectors can be calculated based on the reference signal determined and the complex-valued measurement signals.

In an embodiment, the complex-valued measurement signals may be processed in order to obtain measured symbol streams having measured symbols that are further processed in a constellation layer in order to determine constellation points. Hence, clusters of the complex symbols received are analyzed in order to identify the probable symbols transmitted. Based thereon, reference symbols are generated in order to obtain the reference signal.

This can be done for the complex-valued measurement signals of each reception branch 18 separately or for all complex-valued measurement signals received via all reception branches 18.

In an embodiment, each receiver 51, 52 in each reception branch 18 receives a respective complex-valued measurement signal \tilde{t} such that the entire measurement instrument 12 gathers the several complex-valued measurement signals:

$$\tilde{t} := {\tilde{t}}^{( u )} := ( \begin{matrix}{\tilde{t}}^{( u , 1 )} \\ ⋮ \\ {\tilde{t}}^{( u , m )}\end{matrix} ) ,$$

wherein u∈{1, 2} in case of two receivers 51, 52 per reception branch 18. Generally, u∈{1 . . . r} for the respective number of receivers per reception branch. Moreover, m designates the number of transmission antennas 15 of the device under test 14.

\tilde{t}^{(u,p)} is the complex-valued measurement signal received by the respective receiver u in the reception branch 18 associated with the transmission antenna p. Consequently, \tilde{t}^{(u)} relates to the complex-valued measurement signals, namely the respective complex-valued measurement symbols associated with the complex-valued measurement signals, based on which the MIMO decoding respective transmission demapping is done.

The MIMO decoding respective transmission demapping can be expressed as follows:

$$\tilde{s} = {M}^{- 1} * \tilde{t} ,$$

wherein \tilde{s} relates to measured symbol streams obtained after MIMO decoding respective transmission demapping, e.g. applying the transmission demapping M⁻¹ on the complex-valued measurement signals received, e.g. the respective complex-valued measurement symbols.

AS indicated above, the measured symbols streams \tilde{s} are further processed for symbol decision in the constellation diagram layer in order to determine the corresponding symbols s_{dec} (on reception site). This can be expressed as follows:

s_{dec}:=decide(\tilde{s}).

These symbols s_{dec} obtained are deemed to relate to the symbols s used by the device under test 14 prior to MIMO mapping (on transmission site), namely the “real transmitted symbols”. This can be expressed as follows:

s≅s_{dec}.

Finally, these symbols s_{dec} are used to generate the reference symbols t_{ref} for the at least one reference signal, namely by a MIMO encoding respective transmission mapping, e.g. applying the transmission mapping M on the symbols. This can be expressed as follows:

$${t}_{ref} = M * {s}_{dec} .$$

As indicated above, the reference symbols t_{ref} obtained relate to the at least one reference signal t that is used for calculating the quality vectors.

Consequently, the at least one reference signal t may be derived from the several complex-valued measurement signals.

In other words, a signal portion for each transmission antenna 15 may be determined, namely the symbols originally transmitted by each transmission antenna 15. The signal portions determined together form the signal to be transmitted by the device under test 12.

As described above, decisions with regard to the respective symbols are made in the constellation diagram layer such that the probable symbols transmitted are obtained, e.g. the sequences of symbols or symbol streams, based on which the individual transmission signals were generated.

In an embodiment, the signal portions determined for each transmission antenna 15 correspond to the reference signals for the transmission antennas 15 such that the reference signals are determined from the complex-valued measurement signals.

Afterwards, the different quality vectors can be calculated based on the complex-valued measurement signals and the reference signals determined.

Consequently, it is possible to perform cross-correlation for MIMO ECM measurements by calculating the quality metric, e.g. the EVM, in the antenna plane/layer/domain of the device under test 14.

Certain embodiments disclosed herein include systems, apparatus, modules, units, devices, components, etc., that utilize circuitry (e.g., one or more circuits) in order to implement standards, protocols, methodologies or technologies disclosed herein, operably couple two or more components, generate information, process information, analyze information, generate signals, encode/decode signals, convert signals, transmit and/or receive signals, control other devices, etc. Circuitry of any type can be used. It will be appreciated that the term “information” can be use synonymously with the term “signals” in this paragraph. It will be further appreciated that the terms “circuitry,” “circuit,” “one or more circuits,” etc., can be used synonymously herein.

In an embodiment, circuitry includes, among other things, one or more computing devices such as a processor (e.g., a microprocessor), a central processing unit (CPU), a digital signal processor (DSP), an application-specific integrated circuit (ASIC), a field programmable gate array (FPGA), a system on a chip (SoC), or the like, or any combinations thereof, and can include discrete digital or analog circuit elements or electronics, or combinations thereof. In an embodiment, circuitry includes hardware circuit implementations (e.g., implementations in analog circuitry, implementations in digital circuitry, and the like, and combinations thereof).

In an embodiment, circuitry includes combinations of circuits and computer program products having software or firmware instructions stored on one or more computer readable memories that work together to cause a device to perform one or more protocols, methodologies or technologies described herein. In an embodiment, circuitry includes circuits, such as, for example, microprocessors or portions of microprocessor, that require software, firmware, and the like for operation. In an embodiment, circuitry includes an implementation comprising one or more processors or portions thereof and accompanying software, firmware, hardware, and the like.

For example, the functionality described herein can be implemented by special purpose hardware-based computer systems or circuits, etc., or combinations of special purpose hardware and computer instructions. Each of these special purpose hardware-based computer systems or circuits, etc., or combinations of special purpose hardware circuits and computer instructions form specifically configured circuits, machines, apparatus, devices, etc., capable of implemented the functionality described herein.

Of course, in some embodiments, two or more of these components, or parts thereof, can be integrated or share hardware and/or software, circuitry, etc. In some embodiments, these components, or parts thereof, may be grouped in a single location or distributed over a wide area. In circumstances where the components are distributed, the components are accessible to each other via communication links.

In an embodiment, one or more of the components of the measurement instrument 12 and/or the device under test 14 described herein include circuitry programmed to carry out one or more steps of any of the methods disclosed herein. In some embodiments, one or more computer-readable media associated with or accessible by such circuitry contains computer readable instructions embodied thereon that, when executed by such circuitry, cause the component or circuitry to perform one or more steps of any of the methods disclosed herein.

In an embodiment, the computer readable instructions include applications, programs, program modules, scripts, source code, program code, object code, byte code, compiled code, interpreted code, machine code, executable instructions, and/or the like (also referred to herein as executable instructions, instructions for execution, program code, computer program instructions, and/or similar terms used herein interchangeably).

In an embodiment, computer-readable media is any medium that stores computer readable instructions, or other information non-transitorily and is directly or indirectly accessible to a computing device, such as processor circuitry, etc., or other circuitry disclosed herein etc. In other words, a computer-readable medium is a non-transitory memory at which one or more computing devices can access instructions, codes, data, or other information. As a non-limiting example, a computer-readable medium may include a volatile random access memory (RAM), a persistent data store such as a hard disk drive or a solid-state drive, or a combination thereof. In some embodiments, memory can be integrated with a processor, separate from a processor, or external to a computing system.

Accordingly, blocks of the block diagrams and/or flowchart illustrations support various combinations for performing the specified functions, combinations of operations for performing the specified functions and program instructions for performing the specified functions. These computer program instructions may be loaded onto one or more computer or computing devices, such as special purpose computer(s) or computing device(s) or other programmable data processing apparatus(es) to produce a specifically-configured machine, such that the instructions which execute on one or more computer or computing devices or other programmable data processing apparatus implement the functions specified in the flowchart block or blocks and/or carry out the methods described herein. Again, it should also be understood that each block of the block diagrams and flowchart illustrations, and combinations of blocks in the block diagrams and/or flowchart illustrations, or portions thereof, could be implemented by special purpose hardware-based computer systems or circuits, etc., that perform the specified functions or operations, or combinations of special purpose hardware and computer instructions.

It should now be appreciated that embodiments of the present disclosure, or portions thereof, have been described in the general context of computer code or machine-useable instructions, including computer-executable instructions such as program modules, being executed by a computing system, or other machine or machines. Some of these embodiments or others may be implemented using a variety of system configurations, including handheld devices, consumer electronics, general-purpose computers, more specialty computing devices, etc. Embodiments described herein may also be implemented in distributed computing environments, using remote-processing devices that are linked through a communications network or the Internet.

In the foregoing description, specific details are set forth to provide a thorough understanding of representative embodiments of the present disclosure. It will be apparent to one skilled in the art, however, that the embodiments disclosed herein may be practiced without embodying all of the specific details. In some instances, well-known process steps have not been described in detail in order not to unnecessarily obscure various aspects of the present disclosure.

In the detailed description herein, references to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. In addition, when a particular feature, structure, or characteristic is described in connection with an embodiment, it is submitted that it is within the knowledge of one skilled in the art to affect such feature, structure, or characteristic in connection with other embodiments whether or not explicitly described. After reading the description, it will be apparent to one skilled in the relevant art(s) how to implement the disclosure in alternative embodiments. Thus, it will be appreciated that embodiments of the present disclosure may employ any combination of features described herein. All such combinations or sub-combinations of features are within the scope of the present disclosure.

Although the method and various embodiments thereof have been described as performing sequential steps, the claimed subject matter is not intended to be so limited. As nonlimiting examples, the described steps need not be performed in the described sequence and/or not all steps are required to perform the method. Moreover, embodiments are contemplated in which various steps are performed in parallel, in series, and/or a combination thereof. As such, one of ordinary skill will appreciate that such examples are within the scope of the claimed embodiments.

The present application may reference quantities and numbers. Unless specifically stated, such quantities and numbers are not to be considered restrictive, but exemplary of the possible quantities or numbers associated with the present application. Also in this regard, the present application may use the term “plurality” to reference a quantity or number. In this regard, the term “plurality” is meant to be any number that is more than one, for example, two, three, four, five, etc. The terms “about,” “approximately,” “near,” etc., mean plus or minus 5% of the stated value. For the purposes of the present disclosure, the phrase “at least one of A and B” is equivalent to “A and/or B” or vice versa, namely “A” alone, “B” alone or “A and B.”. Similarly, the phrase “at least one of A, B, and C,” for example, means (A), (B), (C), (A and B), (A and C), (B and C), or (A, B, and C), including all further possible permutations when greater than three elements are listed.

Throughout this specification, terms of art may be used. These terms are to take on their ordinary meaning in the art from which they come, unless specifically defined herein or the context of their use would clearly suggest otherwise.

The drawings in the FIGURES are not to scale. Similar elements are generally denoted by similar references in the FIGURES. For the purposes of this disclosure, the same or similar elements may bear the same references. Furthermore, the presence of reference numbers or letters in the drawings cannot be considered limiting, even when such numbers or letters are indicated in the claims.

The principles, representative embodiments, and modes of operation of the present disclosure have been described in the foregoing description. However, aspects of the present disclosure which are intended to be protected are not to be construed as limited to the particular embodiments disclosed. Further, the embodiments described herein are to be regarded as illustrative rather than restrictive. It will be appreciated that variations and changes may be made by others, and equivalents employed, without departing from the spirit of the present disclosure. Accordingly, it is expressly intended that all such variations, changes, and equivalents fall within the spirit and scope of the present disclosure, as claimed.

The embodiments of the invention in which an exclusive property or privilege is claimed are defined as follows:

1. A method of determining a quality metric for a device under test having multiple transmission antennas for transmitting multiple transmission signals, the method comprising:
receiving each of the multiple transmission signals by a respective reception antenna connected to a corresponding reception branch having at least a first receiver and a second receiver, wherein the first receiver and the second receiver both receive and process the same transmission signal, thereby providing a first complex-valued measurement signal and a second complex-valued measurement signal respectively,
providing at least one reference signal that is associated with a signal to be transmitted by the device under test,
calculating a first quality vector for the first receiver based on the first complex-valued measurement signal and a second quality vector for the second receiver based on the second complex-valued measurement signal, wherein the quality vectors are calculated with respect to the at least one reference signal,
determining a combined average of the first quality vector and of a complex conjugate of the second quality vector over a predetermined number of samples, thereby obtaining a complex-valued average signal, and
determining a quality metric based on the complex-valued average signal.

2. The method according to claim 1, wherein each complex-valued measurement signal comprises a symbol sequence associated with the respective transmission signal, and wherein the symbol sequences received are processed in order to calculate the quality vectors.

3. The method according to claim 1, wherein the at least one reference signal is inputted to a detector circuit that calculates the respective quality vectors based on the reference signal inputted and the complex-valued measurement signals.

4. The method according to claim 1, wherein the at least one reference signal is determined by a detector circuit from processing the complex-valued measurement signals, and wherein the respective quality vectors are calculated based on the reference signal determined and the complex-valued measurement signals.

5. The method according to claim 1, wherein the complex-valued measurement signals are processed in a constellation layer in order to determine constellation points for the complex-valued measurement signals.

6. The method according to claim 1, wherein a transmission demapping is applied to obtain symbol streams from the complex-valued measurement signals.

7. The method according to claim 1, wherein the quality metric is determined for each of the multiple transmission antennas individually.

8. The method according to claim 1, wherein the quality metric is determined for all of the multiple transmission antennas commonly.

9. The method according to claim 1, wherein the quality vectors are averaged in time and/or frequency.

10. The method according to claim 1, wherein the quality vectors are error vectors and the quality metric is an error vector magnitude.

11. A method of determining a quality metric for a device under test having multiple transmission antennas for transmitting multiple transmission signals, the method comprising:
receiving each of the multiple transmission signals by a respective reception antenna connected to a corresponding reception branch having at least a first receiver and a second receiver, wherein the first receiver and the second receiver both receive and process the same transmission signal, thereby providing a first complex-valued measurement signal and a second complex-valued measurement signal respectively,
providing at least one reference signal that is associated with a signal to be transmitted by the device under test,
calculating a first quality vector for the first receiver based on the first complex-valued measurement signal and a second quality vector for the second receiver based on the second complex-valued measurement signal, wherein the quality vectors are calculated with respect to the at least one reference signal,
cross-correlating the first quality vector and the second quality vector, thereby obtaining a cross-correlated signal, and
determining a quality metric based on the cross-correlated signal.

12. A measurement system for determining a quality metric for a device under test having multiple transmission antennas for transmitting multiple transmission signals, wherein the measurement system comprises multiple reception branches and at least one detector circuit, wherein the at least one detector circuit has a first signal input, a second signal input, and an averaging sub-circuit,
wherein each reception branch is configured to receive one of the multiple transmission signals, wherein each reception branch comprises at least two receivers such that the at least two receivers of the same reception branch receive and process the same transmission signal, thereby providing a first complex-valued measurement signal and a second complex-valued measurement signal respectively,
wherein the first signal input is connected with the first receiver and configured to receive the first complex-valued measurement signal,
wherein the second signal input is associated with the second receiver and configured to receive the second complex-valued measurement signal,
wherein the detector circuit is configured to calculate a first quality vector for the first receiver based on the first complex-valued measurement signal and a second quality vector for the second receiver based on the second complex-valued measurement signal, wherein the quality vectors are calculated with respect to a reference signal provided which is associated with a signal to be transmitted by the device under test,
wherein the averaging sub-circuit is configured to determine a combined average of the first quality vector and of a complex conjugate of the second quality vector over a predetermined number of samples, thereby obtaining a complex-valued average signal, and
wherein the averaging sub-circuit is configured to determine a quality metric based on the complex-valued average signal.

13. The measurement system according to claim 12, wherein the measurement system comprises a measurement instrument that comprises the multiple reception branches and the at least one detector circuit, wherein each of the reception branches is connected to a respective reception antenna, wherein each of the reception branches has at least two parallel measurement channels having the respective receiver, and wherein the measurement system further comprises a separately formed device under test with the multiple transmission antennas via which the multiple transmission signals are transmitted over-the-air, which are received by the multiple reception antennas of the measurement instrument.

14. The measurement system according to claim 13, wherein the measurement instrument is configured for transmission demapping to obtain symbol streams from the complex-valued measurement signals.

15. The measurement system according to claim 14, wherein the measurement instrument is configured to process the symbol streams obtained in a constellation diagram layer.

16. The measurement system according to claim 12, wherein the at least one detector circuit is configured to average the quality vectors in time and/or frequency.

17. The measurement system according to claim 12, wherein the at least one detector circuit is configured to determine the quality metric for each of the multiple transmission antennas individually.

18. The measurement system according to claim 12, wherein the at least one detector circuit is configured to determine the quality metric for all of the multiple transmission antennas commonly.

19. The measurement system according to claim 12, wherein the at least one detector circuit has an input configured to receive the at least one reference signal, and wherein the at least one detector circuit is configured to calculate the respective quality vectors based on the reference signal inputted and the complex-valued measurement signals.

20. The measurement system according to claim 12, wherein the at least one detector circuit is configured to determine the at least one reference signal from processing the complex-valued measurement signals, and wherein at least one detector circuit is configured to calculate the respective quality vectors based on the reference signal determined and the complex-valued measurement signals.
